(19) United States
(12) Patent Application Publication
(10) Pub. No.: US 2020/0321475 A1
(43) Pub. Date: Oct. 8, 2020

(54) MANUFACTURING METHOD FOR LTPS TFT SUBSTRATE

(71) Applicant: Wuhan China Star Optoelectronics Technology Co., Ltd., Wuhan (CN)

(72) Inventors: Xin Zhang, Wuhan (CN); Juncheng Xiao, Wuhan (CN); Haifeng Chen, Wuhan (CN); Haijun Tian, Wuhan (CN); Yanqing Guan, Wuhan (CN); Chao Tian, Wuhan (CN)

(21) Appl. No.: 16/308,814

(22) PCT Filed: Sep. 22, 2018
(86) PCT No.: PCT/CN2018/107151

§ 371 Date: Dec. 10, 2018

(30) Foreign Application Priority Data
May 18, 2018 (CN) 201810482889.X

(51) Int. Cl. H01L 29/786; H01L 27/12; H01L 21/265; H01L 29/66

(52) U.S. Cl. CPC H01L 29/78621; H01L 27/1222; H01L 29/78633; H01L 29/78675; H01L 29/66757; H01L 27/1288; H01L 21/26513; H01L 29/66492; H01L 27/127

(57) ABSTRACT

A manufacturing method for LTPS TFT substrate is disclosed. Through performing two etchings on the gate metal layer, ion heavy doping and ion light doping of the polysilicon active layer are performed in a self-aligned manner such that the LDD structure of the polysilicon active layer is symmetrically distributed on two sides of the gate electrode, which is beneficial to improve device characteristics, is more stable and reliable than the conventional technology, and can reduce the number of process masks, save mask cost, operation cost, material cost and the time cost. The thinning process of the gate insulation layer can reduce the thickness of the gate insulation layer corresponding to the heavily doped region of the polysilicon active layer, so that the ion implantation efficiency can be effectively improved.

### FIELD OF THE INVENTION

The present invention relates to a display technology field, and more particularly to a manufacturing method for LTPS TFT substrate.

### BACKGROUND OF THE INVENTION

In the field of display technology, flat panel display devices such as liquid crystal display (LCD) and active matrix organic light-emitting diode (AMOLED) displays have many advantages such as thin body and high image quality, power saving, no radiation such that they have been widely used, such as mobile phones, personal digital assistants (PDAs), digital cameras, computer screens or notebook screens.

Thin film transistor (TFT) array substrate is a main component of current LCD devices and AMOLED device. It is directly related to the development direction of high-performance flat panel display devices. It is used to provide a driving circuit to the display device, and usually provides with multiple gate scanning lines and multiple data lines, the multiple gate scanning lines and the multiple data lines define multiple pixel units, each of which is provided with a thin-film transistor and a pixel electrode, and a gate electrode of the thin-film transistor is connected to a corresponding gate scan line. When the voltage on the gate scanning line reaches the turn-on voltage, the source and drain of the thin-film transistor are turned on, thereby inputting the data voltage on the data line to the pixel electrode, thereby controlling the corresponding pixel region to display. Generally, the structure of the thin-film transistor on the array substrate further includes a gate electrode, a gate insulation layer, an active layer, a source and a drain, and an insulation protection layer which are stacked on the substrate.

Wherein, the low temperature poly-Silicon (LTPS) thin-film transistors are more complicated than traditional amorphous silicon (A-Si) thin-film transistors, but they are widely used for the production of small and medium-sized high-resolution LCD and AMOLED display panels because of high carrier mobility. The low-temperature polysilicon is regarded as an important material for low-cost full-color flat panel display.

The hot carrier effect is an important failure mechanism of the Metal Oxide Semiconductor (MOS) devices. With the shrinking size of MOS devices, the hot carrier injection effect of devices is becoming more and more serious. In the LTPS array technology, in order to effectively suppress the hot carrier effect of the device, improve the stability of the device operation and improve the leakage current of the device under negative bias conditions, the existing LTPS TFT fabrication process usually adopts a lightly doped drain region (LDD), that is, a low-doped region is placed in the poly-silicon (Poly-Si) channel near the source and drain, so that the low-doped region is also subjected to partial dividing voltage to ensure the device characteristic.

The prior art form an LDD structure by performing an ion implantation of heavy doping and light doping to the polysilicon by a photomask. Using an N-type MOS (NMOS) device as an example, the process of manufacturing an LTPS array substrate includes the following steps:

Step S10, as shown in FIG. 1, sequentially forming a buffering layer 200 and a polysilicon active layer 300 on a substrate 100;

Step S20, as shown in FIG. 2, coating a photoresist on the polysilicon active layer 300, and forming a first photoresist pattern 980 is by exposure and development through one photomask, and using the first photoresist pattern 980 as a shielding layer, implanting a high dose of N-type ions (phosphorus ions P+, 1×10¹⁴˜1×10¹⁵ ions/cm²) to two ends of the polysilicon active layer 300 to form a heavily doped region (N+) 310;

Step S30, as shown in FIG. 3, stripping and removing the photoresist pattern 980, and depositing to form a gate insulation layer 400 covering the polysilicon active layer 300 on the buffering layer 200. Depositing a first metal layer on the gate insulation layer 400, forming a second photoresist pattern 990 on the first metal layer, and etching the first metal layer by using the second photoresist pattern 990 as a shielding layer. Forming a gate electrode 500 above the corresponding polysilicon active layer 300 to form a channel region;

Step S40, as shown in FIG. 4, using the gate electrode 500 as a shielding layer, and implanting low-dose N-type ions (P+, 1×10¹²˜1×10¹³ ions/cm²) into the polysilicon active layer 300 to form a channel region 320 and a lightly doped region (N−) 330 between the channel region 320 and the heavily doped region 310.

The above method for manufacturing the LTPS array substrate requires a large number of photomasks, and forming a heavily doped region 310 by doping on the polysilicon active layer 300 through a photomask, and then doping the lightly doped region 330 by the self-alignment of the gate electrode 500 to form an LDD structure. Since the heavily doped region 310 is doped by the photomask, the heavily doped region 310 may be asymmetric at two ends of the polysilicon active layer 300 due to the alignment deviation or the like, and the LDD structure formed after light doping may be asymmetric at two ends of the polysilicon active layer 300, and may be too small on one side and too small, and the LDD region being too small or too large may affect the characteristics and stability of the device.

Therefore, in the manufacturing method of the conventional LTPS array substrate, it is difficult to achieve the symmetry of the LDD region at both ends of the active layer due to the alignment deviation, and the asymmetry of the LDD region may result in poor device characteristics and affect product quality.

How to effectively reduce the production cycle of LTPS array substrate, improve product yield, effectively improve product production capacity and reduce cost is the focus of the panel design industry and an effective way to increase the company's market competitiveness.

### SUMMARY OF THE INVENTION

An object of the present invention is to provide a manufacturing method for LTPS TFT substrate, which can make the LDD structure of the polysilicon active layer symmetrically distributed on two sides of the gate electrode, which is beneficial to improving device characteristics, and is more stable and reliable than conventional techniques, and reducing the number of process photomasks, saving mask costs, operating costs, material costs and time costs at the same time.

In order to achieve the above purpose, the present invention provides a manufacturing method for LTPS TFT substrate, comprising steps of:

step S1, providing a base substrate, forming a buffering layer on the base substrate, forming a polysilicon material layer on the buffering layer, and patterning the polysilicon material layer to obtain a polysilicon active layer;

step S2, forming a gate insulation layer covering the polysilicon active layer and depositing a gate metal layer on the gate insulation layer;

step S3, coating a photoresist on the gate metal layer, and after exposure and development, a photoresist layer corresponding to and located above a middle portion of the polysilicon active layer is obtained, and using the photoresist layer a shielding layer, performing a first etching to the gate metal layer in order to form a quasi-gate electrode located above the middle portion of the polysilicon active layer;

step S4, using the photoresist layer and the quasi-gate electrode as a shielding layer, and etching the gate insulation layer to decrease a thickness of upper two ends of the gate insulation layer above the polysilicon active layer;

step S5, using the photoresist layer and the quasi-gate electrode as a shielding layer, performing an ion heavy doping to the polysilicon active layer to form a source-drain contact region at two ends of the polysilicon active layer;

step S6, performing a second etching to the gate metal layer such that two sides of the quasi-gate electrode are laterally etched and a width of the quasi-gate electrode is decreased, and a gate electrode is obtained from the quasi-gate electrode, and stripping and removing photoresist layer; and

step S7, using the gate electrode as a shielding layer to perform an ion light doping to the polysilicon active layer in order to obtain a channel region located at a middle portion of the polysilicon active layer and corresponding to a bottom of the quasi-gate electrode, and obtain a LDD region located between the source-drain contact region and the channel region.

Wherein an etching depth of the gate insulation layer in the step S4 is 100 Å˜1500 Å.

Wherein a thickness of the gate insulation layer formed in the step S2 is 300 Å˜2500 Å

Wherein in the step S5, an ion doping concentration when performing the ion heavy doping to the polysilicon active layer is 1×10¹³-1×10¹⁵ ions/cm².

Wherein in the step S7, the doping ion concentration when performing the ion light doping to the polysilicon active layer is 1×10¹²-1×10¹⁴ ions/cm².

Wherein in the step S5, the ion heavy doping to the polysilicon active layer is an N-type ion heavy doping, and the doped ions are phosphorus; and

in the step S7, the ion light doping to the polysilicon active layer is an N-type ion light doping, and the doped ions are phosphorus.

Wherein in the step S5, the ion heavy doping to the polysilicon active layer is a P-type ion heavy doping, and the doped ions are boron; and

in the step S7, the ion light doping to the polysilicon active layer is a P-type ion light doping, and the doped ions are boron.

Wherein the step S1 further comprises a step of performing a channel doping to the polysilicon active layer after patterning to form the polysilicon active layer.

Wherein in the step S1, a doping ion concentration when performing the channel doping to the polysilicon active layer is 1×10¹¹-1×10¹³ ions/cm².

Wherein the step S1 further comprises a step of forming a light-shielding block correspondingly located below the polysilicon active layer on the substrate.

Advantageous effects of the present invention: the manufacturing method for LTPS TFT substrate of the present invention, through performing two etchings on the gate metal layer, ion heavy doping and ion light doping of the polysilicon active layer are performed in a self-aligned manner such that the LDD structure of the polysilicon active layer is symmetrically distributed on two sides of the gate electrode, which is beneficial to improve device characteristics, is more stable and reliable than the conventional technology, and can reduce the number of process masks, save mask cost, operation cost, material cost and the time cost. The thinning process of the gate insulation layer (GI Loss) can reduce the thickness of the gate insulation layer corresponding to the heavily doped region of the polysilicon active layer, so that the ion implantation efficiency can be effectively improved.

### BRIEF DESCRIPTION OF THE DRAWINGS

In order to further understand the features and technical contents of the present invention, please refer to the following detailed description and drawings regarding the present invention. The drawings are provided for purposes of illustration and description only and are not intended to be limiting.

In the drawings,

FIG. 1 is a schematic diagram of a step S10 of manufacturing LTPS TFT substrate in the prior art.

FIG. 2 is a schematic diagram of a step S20 of manufacturing LTPS TFT substrate in the prior art.

FIG. 3 is a schematic diagram of a step S30 of manufacturing LTPS TFT substrate in the prior art.

FIG. 4 is a schematic diagram of a step S40 of manufacturing LTPS TFT substrate in the prior art.

FIG. 5 is a schematic flow chart of a manufacturing method for LTPS TFT substrate of the present invention.

FIG. 6 is a schematic diagram of step S1 of the manufacturing method for LTPS TFT substrate of the present invention.

FIG. 7 is a schematic diagram of step S2 of the manufacturing method for LTPS TFT substrate of the present invention.

FIG. 8 is a schematic diagram of step S3 of the manufacturing method for LTPS TFT substrate of the present invention.

FIG. 9 is a schematic diagram of step S4 of the manufacturing method for LTPS TFT substrate of the present invention.

FIG. 10 is a schematic diagram of step S5 of the manufacturing method for LTPS TFT substrate of the present invention.

FIG. 11 is a schematic diagram of step S6 of the manufacturing method for LTPS TFT substrate of the present invention.

FIG. 12 is a schematic diagram of step S7 of the manufacturing method for LTPS TFT substrate of the present invention.

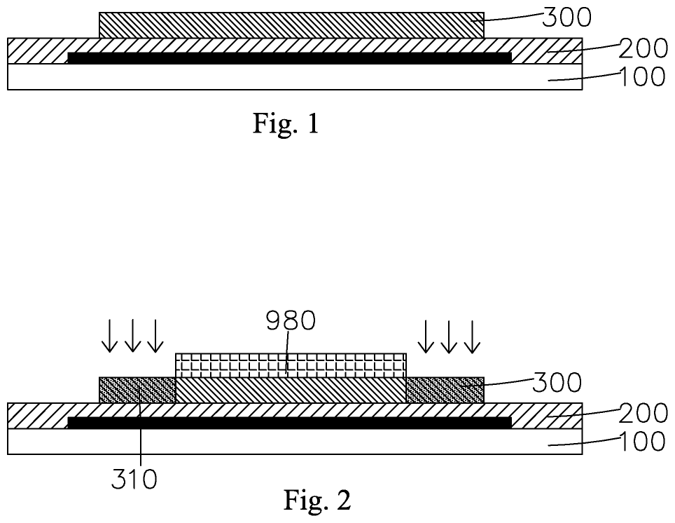

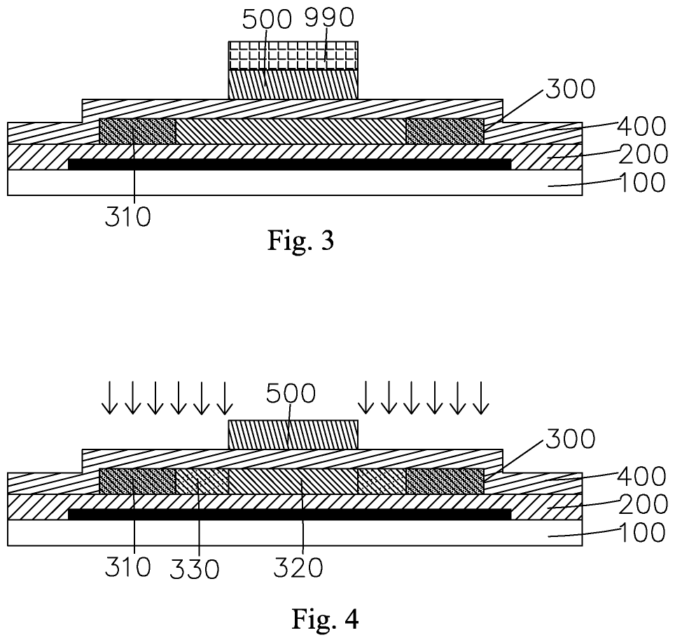

### DETAILED DESCRIPTION OF PREFERRED EMBODIMENTS

In order to further describe the technical means and effects of the present invention in detail, the following detailed description will be made in conjunction with the preferred embodiments of the invention and the accompanying drawings.

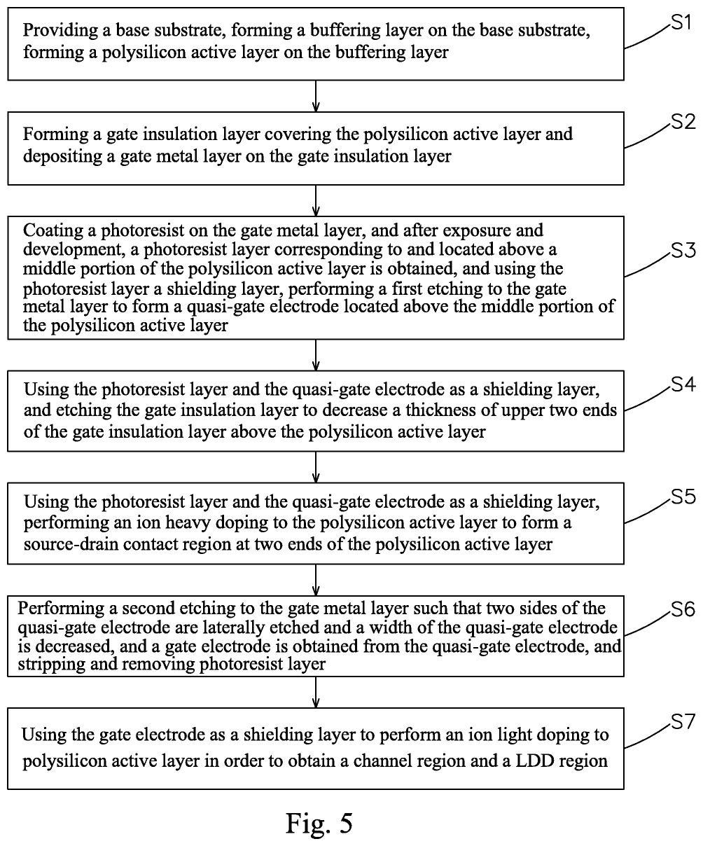

Referring to FIG. 5, the present invention provides a manufacturing method for LTPS TFT substrate, including the following steps:

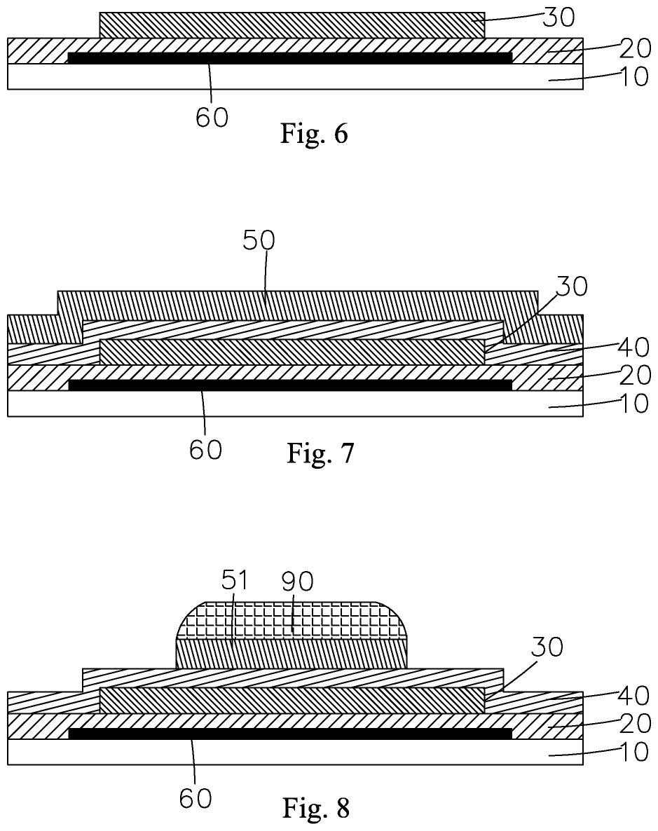

Step S1, as shown in FIG. 6, providing a base substrate 10, and sequentially forming a light-shielding block 60 and a buffering layer 20 covering the light-shielding block 60 on the base substrate 10. Forming a polysilicon material layer on the buffering layer 20, and patterning the polysilicon material layer to obtain a polysilicon active layer 30; then performing a channel doping to the polysilicon active layer 30.

Specifically, in the step S1, a doping ion concentration when performing the channel doping to the polysilicon active layer 30 is 1×10¹¹-1×10¹³ ions/cm².

Specifically, in the step S1, the manufacturing process for the polysilicon layer is: depositing an amorphous silicon material on the buffering layer 20, and using a low temperature crystallization process to convert the amorphous silicon material into a polysilicon material. The low temperature crystallization process is solid phase crystallization, excimer laser crystallization, rapid thermal annealing, or metal lateral induction.

Step S2, as shown in FIG. 7, forming a gate insulation layer 40 covering the polysilicon active layer 30 on the buffering layer 20, and depositing a gate metal layer 50 on the gate insulation layer 40.

Specifically, the gate insulation layer 40 is a silicon oxide layer, a silicon nitride layer, or a combination of the two.

Specifically, a thickness of the gate insulation layer 40 formed in the step S2 is 300 Å˜2500 Å.

Step S3, as shown in FIG. 8, coating a photoresist on the gate metal layer 50, and after exposure and development, a photoresist layer 90 corresponding to and located above a middle portion of the polysilicon active layer 30 is obtained, and using the photoresist layer 90 a shielding layer, performing a first etching to the gate metal layer 50 in order to form a quasi-gate electrode 51 located above the middle portion of the polysilicon active layer 30.

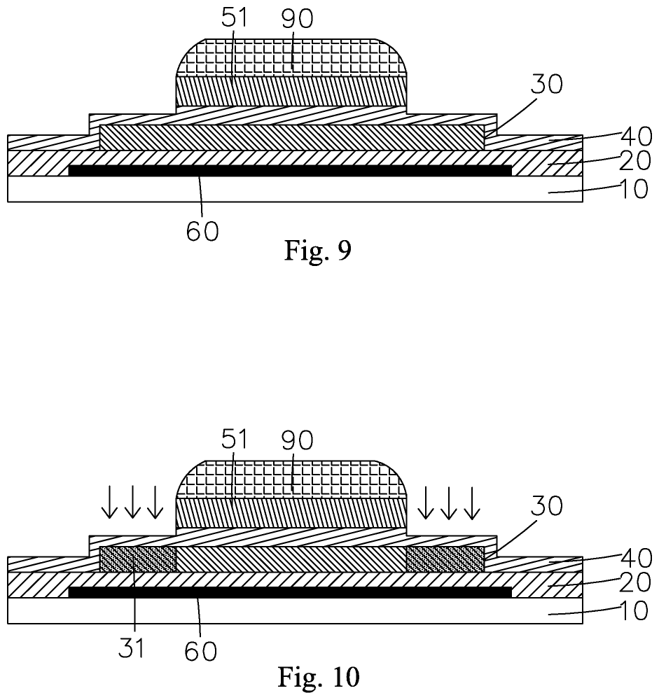

Step S4, as shown in FIG. 9, using the photoresist layer 90 and the quasi-gate electrode 51 as a shielding layer, and etching the gate insulation layer 40 to decrease a thickness of upper two ends of the gate insulation layer 40 above the polysilicon active layer 30, that is, a thickness of a region of the gate insulation layer 40 above the polysilicon active layer 30 for subsequently performing a heavy doping such that the gate insulation layer 40 above the polysilicon active layer 30 forms a convex structure.

Specifically, an etching depth of the gate insulation layer 40 in the step S4 is 100 Å˜1500 Å, which can effectively improve the ion implantation efficiency of the subsequent heavy doping.

Step S5, as shown in FIG. 10, using the photoresist layer 90 and the quasi-gate electrode 51 as a shielding layer, performing an ion heavy doping to the polysilicon active layer 30 to form a source-drain contact region 31 at two ends of the polysilicon active layer 30.

Specifically, in the step S5, an ion doping concentration when performing the ion heavy doping to the polysilicon active layer 30 is 1×10¹³-1×10¹⁵ ions/cm².

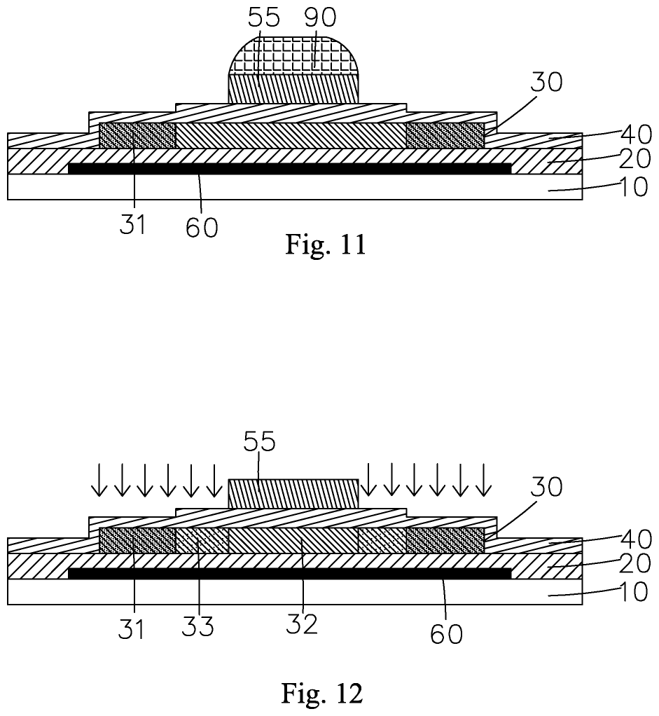

Step S6, as shown in FIG. 11, performing a second etching to the gate metal layer 50 such that two sides of the quasi-gate electrode 51 are laterally etched and a width of the quasi-gate electrode 51 is decreased, and a gate electrode 55 is obtained from the quasi-gate electrode 51, and stripping and removing photoresist layer 90.

Specifically, in the step S6, since the thickness at the edge of the photoresist layer 90 is thinner, part of the photoresist layer 90 is etched while etching the gate metal layer 50, and the thinner portion at the edge of the photoresist layer 90 can be completely etched. Portions of the gate metal layer 50 that are not protected by the photoresist layer 90 are etched away, so that the widths of two sides of the quasi-gate electrode 51 are decreased.

Step S7, as shown in FIG. 12, using the gate electrode 55 as a shielding layer to perform an ion light doping to the polysilicon active layer 30 in order to obtain a channel region 32 located at a middle portion of the polysilicon active layer 30 and corresponding to a bottom of the quasi-gate electrode 51, and obtain a LDD region 33 located between the source-drain contact region 31 and the channel region 32.

Specifically, in the step S7, the doping ion concentration when performing the ion light doping to the polysilicon active layer 30 is 1×10¹²-1×10¹⁴ ions/cm².

Specifically, the manufacturing method for the LTPS TFT substrate of the present invention is applicable to both NMOS type and PMOS type LTPS TFT substrates, and using NMOS type LTPS TFT substrate as an example, each of the channel doping, the ion heavy doping, and ion light doping to the polysilicon active layer 30 is an N-type ion doping, and the doped ions are phosphorus (P) ions or other N-type element ions. For the same reason, for the PMOS type LTPS TFT substrate, each of the channel doping, the ion heavy doping, and the ion light doping to the polysilicon active layer 30 is a P-type ion doping, and the doped ions are boron (B) ions or other P-type element ions.

The method for fabricating the LTPS TFT substrate of the present invention does not require a photomask for the ion heavy doping and the ion light doping of the polysilicon active layer 30, but is doped by the self-alignment of the gate metal layer 50. Accordingly, the LDD structure at two ends of the polysilicon active layer 30 is symmetrical such that the device is more stable. Performing the first etching to the gate insulation layer 40 such that the thickness of the gate insulation layer 40 corresponding to heavily doping region, that is, the source and drain contact region 31 is different from the thickness of the gate insulation layer 40 corresponding to channel region 32 and the LDD region 33. By thinning the thickness of the gate insulation layer 40 corresponding to the upper portion of the heavily doped region, the ion implantation efficiency can be improved, and the doping ions are effectively injected into the target position to improve the electrical characteristics of the TFT device.

In summary, the manufacturing method for LTPS TFT substrate of the present invention, through performing two etchings on the gate metal layer, ion heavy doping and ion light doping of the polysilicon active layer are performed in a self-aligned manner such that the LDD structure of the polysilicon active layer is symmetrically distributed on two sides of the gate electrode, which is beneficial to improve device characteristics, is more stable and reliable than the conventional technology, and can reduce the number of process masks, save mask cost, operation cost, material cost and the time cost. The thinning process of the gate insulation layer can reduce the thickness of the gate insulation layer corresponding to the heavily doped region of the polysilicon active layer, so that the ion implantation efficiency can be effectively improved.

As described above, for those of ordinary skill in the art, various other changes and modifications can be made in accordance with the technical solutions and the technical concept of the present invention, and all such changes and modifications are intended to fall within the scope of the appended claims.

What is claimed is:

1. A manufacturing method for LTPS TFT substrate, comprising steps of:
step S1, providing a base substrate, forming a buffering layer on the base substrate, forming a polysilicon material layer on the buffering layer, and patterning the polysilicon material layer to obtain a polysilicon active layer;
step S2, forming a gate insulation layer covering the polysilicon active layer and depositing a gate metal layer on the gate insulation layer;
step S3, coating a photoresist on the gate metal layer, and after exposure and development, a photoresist layer corresponding to and located above a middle portion of the polysilicon active layer is obtained, and using the photoresist layer a shielding layer, performing a first etching to the gate metal layer in order to form a quasi-gate electrode located above the middle portion of the polysilicon active layer;
step S4, using the photoresist layer and the quasi-gate electrode as a shielding layer, and etching the gate insulation layer to decrease a thickness of upper two ends of the gate insulation layer above the polysilicon active layer;
step S5, using the photoresist layer and the quasi-gate electrode as a shielding layer, performing an ion heavy doping to the polysilicon active layer to form a source-drain contact region at two ends of the polysilicon active layer;
step S6, performing a second etching to the gate metal layer such that two sides of the quasi-gate electrode are laterally etched and a width of the quasi-gate electrode is decreased, and a gate electrode is obtained from the quasi-gate electrode, and stripping and removing photoresist layer; and
step S7, using the gate electrode as a shielding layer to perform an ion light doping to the polysilicon active layer in order to obtain a channel region located at a middle portion of the polysilicon active layer and corresponding to a bottom of the quasi-gate electrode, and obtain a LDD region located between the source-drain contact region and the channel region.

2. The manufacturing method for LTPS TFT substrate according to claim 1, wherein an etching depth of the gate insulation layer in the step S4 is 100 Å˜1500 Å.

3. The manufacturing method for LTPS TFT substrate according to claim 1, wherein a thickness of the gate insulation layer formed in the step S2 is 300 Å˜2500 Å

4. The manufacturing method for LTPS TFT substrate according to claim 1, wherein in the step S5, an ion doping concentration when performing the ion heavy doping to the polysilicon active layer is 1×10¹³-1×10¹⁵ ions/cm².

5. The manufacturing method for LTPS TFT substrate according to claim 1, wherein in the step S7, the doping ion concentration when performing the ion light doping to the polysilicon active layer is 1×10¹²-1×10¹⁴ ions/cm².

6. The manufacturing method for LTPS TFT substrate according to claim 1, wherein in the step S5, the ion heavy doping to the polysilicon active layer is an N-type ion heavy doping, and the doped ions are phosphorus; and
in the step S7, the ion light doping to the polysilicon active layer is an N-type ion light doping, and the doped ions are phosphorus.

7. The manufacturing method for LTPS TFT substrate according to claim 1, wherein in the step S5, the ion heavy doping to the polysilicon active layer is a P-type ion heavy doping, and the doped ions are boron; and
in the step S7, the ion light doping to the polysilicon active layer is a P-type ion light doping, and the doped ions are boron.

8. The manufacturing method for LTPS TFT substrate according to claim 1, wherein the step S1 further comprises a step of performing a channel doping to the polysilicon active layer after patterning to form the polysilicon active layer.

9. The manufacturing method for LTPS TFT substrate according to claim 8, wherein in the step S1, a doping ion concentration when performing the channel doping to the polysilicon active layer is 1×10¹¹-1×10¹³ ions/cm².

10. The manufacturing method for LTPS TFT substrate according to claim 1, wherein the step S1 further comprises a step of forming a light-shielding block correspondingly located below the polysilicon active layer on the substrate.
